(19) United States
(12) Patent Application Publication
(10) Pub. No.: US 2022/0344610 A1
(43) Pub. Date: Oct. 27, 2022

(54) DISPLAY DEVICE AND METHOD FOR MANUFACTURING DISPLAY DEVICE

(71) Applicant: SHARP KABUSHIKI KAISHA, Sakai City, Osaka (JP)

(72) Inventors: YASUSHI ASAOKA, Sakai City, Osaka (JP); SHIGERU AOMORI, Sakai City, Osaka (JP)

(21) Appl. No.: 17/642,417

(22) PCT Filed: Sep. 20, 2019
(86) PCT No.: PCT/JP2019/037004

§ 371 Date: Mar. 11, 2022

(51) Int. Cl. H01L 51/50; H01L 51/00

(52) U.S. Cl. CPC H01L 51/5056; H01L 51/5072; H01L 51/0034; H01L 2251/5369; H01L 51/502; H01L 51/0005; H01L 27/3211

(57) ABSTRACT

A display device includes a plurality of pixels. Each of the plurality of pixels includes a first electrode, a second electrode, a light-emitting layer provided between the first electrode and the second electrode, a first charge transport layer provided between the first electrode and the light-emitting layer, and a second charge transport layer provided between the second electrode and the light-emitting layer. The first charge transport layer includes a first charge transport material and a first nanofiber.

### TECHNICAL FIELD

The disclosure relates to a display device and a display device manufacturing method.

### BACKGROUND ART

PTL 1 discloses an ejection liquid including quantum dots, which are tiny particles, and a dispersion medium in which the quantum dots are dispersed, an ejection liquid set, a thin film pattern forming method, a thin film, a light-emitting element, an image display device, and an electronic device.

### CITATION LIST

### Patent Literature

PTL 1: JP 2010-009995 A

### SUMMARY

### Technical Problem

In general, since characteristics of a light-emitting element are changed by a charge transport material included in a charge transport layer, charge transport properties suitable for a quantum dot light emitting diode (QLED) are selected, and a solvent (dispersion medium) is also limited depending on the charge transport material. Further, viscosity of a colloidal solution that can be applied (ejected) by ink-jet and includes a charge transport material and a solvent is also limited. Furthermore, when the colloidal solution is applied by ink-jet, there is a problem that drying unevenness (so-called coffee ring) occurs in droplets after the application.

### Solution to Problem

A display device according to an aspect of the disclosure includes a plurality of pixels, wherein each of the plurality of pixels includes a first electrode, a second electrode, a light-emitting layer provided between the first electrode and the second electrode, a first charge transport layer provided between the first electrode and the light-emitting layer, and a second charge transport layer provided between the second electrode and the light-emitting layer, and the first charge transport layer includes a first charge transport material and a first nanofiber.

Further, a manufacturing method for a display device according to an aspect of the disclosure includes forming a charge transport layer by applying, by ink-jet, a colloidal solution including a charge transport material and a nanofiber.

### Advantageous Effects of Disclosure

An aspect of the disclosure can provide a display device in which a quantum dot light-emitting layer being uniform without unevenness in thickness and without cracking is formed.

An aspect of the disclosure can provide a manufacturing method for a display device in which a colloidal solution can be applied (ejected) by ink-jet regardless of viscosity of a solvent, and drying unevenness (so-called coffee ring) does not occur in droplets after the application.

### BRIEF DESCRIPTION OF DRAWINGS

FIG. 1 is a cross-sectional view illustrating a general configuration of a display device according to a first embodiment.

FIG. 2A is a plan view illustrating an example of a process of forming a light-emitting element.

FIG. 2B is a plan view illustrating an example of a process of forming the light-emitting element.

FIG. 2C is a plan view illustrating an example of a process of forming the light-emitting element.

FIG. 3 is a flowchart illustrating a manufacturing method for the display device according to the first embodiment.

FIG. 4 is a diagram schematically illustrating a state of a colloidal solution (droplet) ejected by ink-jet.

FIG. 5 is a plan view schematically illustrating a state of the colloidal solution applied (dropped) onto a substrate and dried, i.e., a light-emitting layer.

FIG. 6 is a cross-sectional view schematically illustrating a state of the colloidal solution applied (dropped) onto the substrate and dried, i.e., the light-emitting layer.

FIG. 7 is a cross-sectional view illustrating a general configuration of a display device according to a second embodiment.

FIG. 8 is a cross-sectional view illustrating a general configuration of a display device according to a third embodiment.

### DESCRIPTION OF EMBODIMENTS

In the following description, an “upper layer” means a layer formed in a process subsequent to a layer as a comparison target. In each drawing, similar configurations are denoted by the same reference sign, and descriptions thereof are omitted.

### First Embodiment

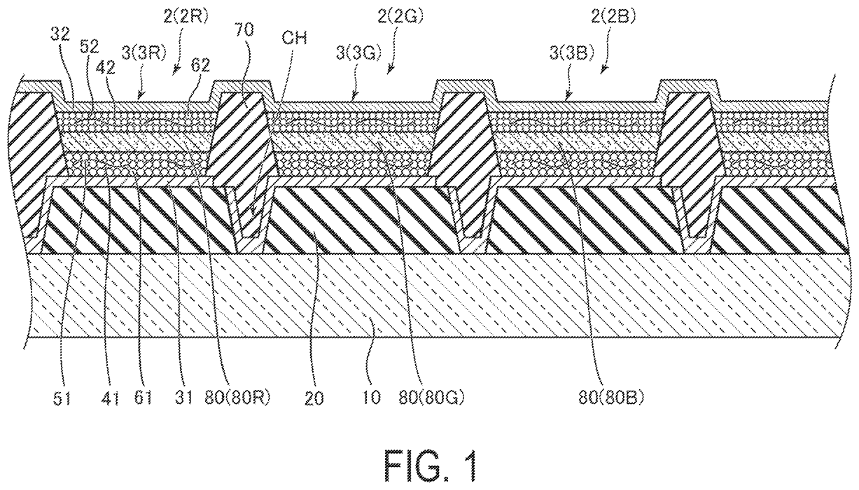

FIG. 1 is a cross-sectional view illustrating a general configuration of a display device 1 according to the present embodiment. The display device 1 is used in a display of a television, a smartphone, and the like, for example. As illustrated in FIG. 1, the display device 1 according to the present embodiment includes a plurality of pixels 2 provided on an array substrate 10.

The plurality of pixels 2 include a red pixel 2R that emits red light, a green pixel 2G that emits green light, and a blue pixel 2B that emits blue light. Each of the plurality of pixels 2 is configured by forming a light-emitting element 3 (a red light-emitting element 3R, a green light-emitting element 3G, and a blue light-emitting element 3B in the red pixel 2R, the green pixel 2G, and the blue pixel 2B, respectively) in a region divided by a bank 70 (pixel regulating layer) that has insulating properties and is provided on an array substrate 10. Note that the red light refers to light having a light-emitting central wavelength in a wavelength band of greater than 600 nm and less than or equal to 780 nm. Further, the green light refers to light having a light-emitting central wavelength in a wavelength band of greater than 500 nm and less than or equal to 600 nm. Further, the blue light refers to light having a light-emitting central wavelength in a wavelength band of greater than or equal to 400 nm and less than or equal to 500 nm.

The array substrate 10 is a substrate provided with a TFT (not illustrated) being a thin film transistor for controlling light emission and non-light emission of each of the light-emitting elements 3. The array substrate 10 according to the present embodiment is configured by forming the TFT on a resin layer having flexibility. Further, the resin layer according to the present embodiment is configured by layering an inorganic insulating film (for example, a silicon oxide film, a silicon nitride film, or a silicon oxynitride film) that is a barrier layer on the resin film (for example, a polyimide film). However, the array substrate 10 may be configured by forming the TFT on a rigid substrate such as a glass substrate. Further, an interlayer insulating film 20 (flattening film) is provided on an upper face of the array substrate 10 according to the present embodiment. The interlayer insulating film 20 is formed of, for example, a polyimide and an acrylic material. A plurality of contact holes CH are formed on the interlayer insulating film 20.

The red light-emitting element 3R, the green light-emitting element 3G, and the blue light-emitting element 3B according to the present embodiment each include a first electrode 31, a first charge transport layer 41, a light-emitting layer 80 (a red light-emitting layer 80R, a green light-emitting layer 80G, and a blue light-emitting layer 80B in the red light-emitting element 3R, the green light-emitting element 3G, and the blue light-emitting element 3B, respectively), a second charge transport layer 42, and a second electrode 32.

The first electrode 31 injects a charge into the first charge transport layer 41. The first electrode 31 according to the present embodiment functions as an anode electrode that injects a positive hole into the first charge transport layer 41. As illustrated in FIG. 1, the first electrode 31 according to the present embodiment is provided in an island shape for each region in which each pixel 2 is formed on the interlayer insulating film 20. Then, the first electrode 31 is electrically connected to the TFT via the contact hole CH provided in the interlayer insulating film 20. The first electrode 31 includes a structure in which a metal including Al, Cu, Au, Ag, or the like having high reflectivity of visible light, and ITO, IZO, ZnO, AZO, BZO, or the like being a transparent material are layered in this order on the array substrate 10, for example. The first electrode 31 is formed by, for example, sputtering, vapor deposition, or the like.

The bank 70 is formed so as to cover the contact hole CH. The bank 70 is formed by, for example, patterning by photolithography after applying an organic material such as a polyimide and an acrylic on the array substrate 10. Further, as illustrated in FIG. 1, the bank 70 according to the present embodiment is formed so as to cover an edge of the first electrode 31. In other words, the bank 70 according to the present embodiment also functions as an edge cover of the first electrode 31. With such a configuration, generation of an excessive electric field at an edge portion of the first electrode 31 can be suppressed.

The first charge transport layer 41 further transports the charge injected from the first electrode 31 to the light-emitting layer 80. The first charge transport layer 41 according to the present embodiment functions as a hole transport layer for transporting the positive hole to the light-emitting layer 80. The first charge transport layer 41 is formed on the first electrode 31, and is electrically connected to the first electrode 31. Specifically, the first charge transport layer 41 is formed in an island shape for each region defining the pixel 2. Note that the first charge transport layer 41 may have a function (positive hole blocking function) of suppressing transport of an electron to the first electrode 31.

The first charge transport layer 41 includes a first charge transport material and a first nanofiber 51. Further, the first charge transport material according to the present embodiment is formed of a first nanoparticle 61. Examples of a material constituting the first nanoparticle 61 include, for example, a metal oxide having hole transport properties such as NiO, Cr₂O₃, MgO, LaNiO₃, MoO₃, and WO₃. The first charge transport layer 41 is formed by an applying method such as an ink-jet method and a spin coating method, for example. Note that details of the first nanofiber 51 will be described below.

The light-emitting layer 80 is provided between the first electrode 31 and the second electrode 32. Specifically, the light-emitting layer 80 according to the present embodiment is provided between the first charge transport layer 41 and the second charge transport layer 42. Further, the light-emitting layer 80 according to the present embodiment includes a quantum dot (semiconductor nanoparticle). Specifically, the light-emitting layer 80 is configured by layering one or more layers of a quantum dot.

The quantum dot is a luminescent material that has a valence band level and a conduction band level and emits light through recombination of a positive hole at the valence band level with an electron at the conduction band level. Light emission from the quantum dot matching in a particle size has a narrower spectrum due to a quantum confinement effect, and thus the light emission with a relatively deep color level can be obtained.

The quantum dot may be, for example, a semiconductor nanoparticle having a core-shell structure including CdSe, InP, ZnTeSe, and ZnTeS in a core, and ZnS in a shell. In addition, the quantum dot may have the core-shell structure such as CdSe/CdS, InP/ZnS, ZnSe/ZnS, or CIGS/ZnS, or may have a double shell structure such as InP/ZnSe/ZnS in which the shell is multilayered. Further, for example, a ligand formed of an organic matter such as thiol and amine may have a coordination bond on an outer peripheral portion of the shell.

The particle size of the quantum dot is approximately from 3 nm to 15 nm. A wavelength of the light emission from the quantum dot can be controlled according to the particle size of the quantum dot. Thus, in the red light-emitting layer 80R, the green light-emitting layer 80G, and the blue light-emitting layer 80B, the light emission of each color can be obtained by using the quantum dot having the particle size controlled.

The second charge transport layer 42 further transports the electron injected from the second electrode 32 to the light-emitting layer 80. The second charge transport layer 42 according to the present embodiment functions as an electron transport layer for transporting the electron to the light-emitting layer 80. Further, the second charge transport layer 42 may have a function (positive hole blocking function) of suppressing transport of a positive hole to the second electrode 32. In the present embodiment, the second charge transport layer 42 is provided on the light-emitting layer 80.

The second charge transport layer 42 includes a second charge transport material and a second nanofiber 52. Further, the second charge transport material according to the present embodiment is formed of a second nanoparticle 62. Further, examples of a material constituting the second nanoparticle 62 include, for example, a material having electron transport properties such as TiO₂, ZnO, ZAO (Al-doped ZnO), ZnMgO, ITO, and InGaZnOₓ. The second charge transport layer 42 is formed by an applying method such as an ink-jet method and a spin coating method, for example. Note that details of the second nanofiber 52 will be described below.

Note that, in the red light-emitting element 3R, the green light-emitting element 3G, and the blue light-emitting element 3B, each of the second charge transport materials included in the second charge transport layer 42 is preferably different. Specifically, the second charge transport material included in the red light-emitting element 3R is preferably a ZnO nanoparticle. Further, the second charge transport material included in the green light-emitting element 3G is preferably an Mg-containing ZnO nanoparticle. The second charge transport material included in the blue light-emitting element 3B is preferably an Mg-containing ZnO nanoparticle having a particle size smaller than that of the second charge transport material included in the green light-emitting element 3G. With such a configuration, an energy level of the second charge transport layer 42 can be adjusted for each luminescent color, and luminous efficiency of each of the light-emitting elements 3 can be improved. However, in the red light-emitting element 3R, the green light-emitting element 3G, and the blue light-emitting element 3B, the second charge transport material included in the second charge transport layer 42 may be the same material from a perspective of manufacturing ease.

The second electrode 32 is provided on the second charge transport layer 42, and is electrically connected to the second charge transport layer 42. The second electrode 32 according to the present embodiment functions as a cathode electrode that injects the electron into the second charge transport layer 42. Further, the second electrode 32 according to the present embodiment is continuously formed across the plurality of pixels 2. The second electrode 32 is formed of, for example, a metal thinned to a degree having optical transparency, and a transparent material. Examples of the metal constituting the second electrode 32 include, for example, a metal including Al, Ag, Mg, and the like. Further, examples of the transparent material constituting the second electrode 32 include, for example, an electrically conductive nanofiber such as ITO, IZO, ZnO, AZO, BZO, or a silver nanofiber. The second electrode 32 is formed by, for example, sputtering, vapor deposition, an applying method, or the like.

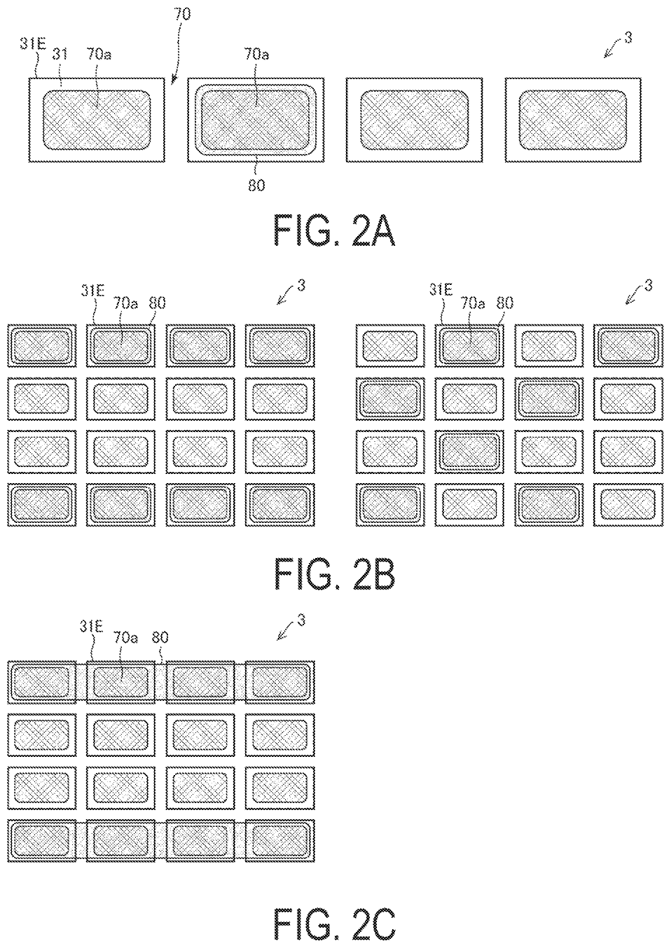

FIGS. 2A to 2C are plan views illustrating an example of a process of forming the light-emitting element 3. FIG. 2A is a plan view illustrating an example of a process of forming each layer in the light-emitting element 3. FIG. 2B is a plan view illustrating an example of a process of forming the light-emitting element 3 in which only a light-emitting layer of one color among light-emitting layers (80R, 80G, 80B) of corresponding colors is formed in an island shape. FIG. 2C is a plan view illustrating an example of a process of forming the light-emitting element 3 in which only a light-emitting layer of one color among the light-emitting layers (80R, 80G, 80B) of corresponding colors is formed in a strip shape. As illustrated in FIG. 2A, the light-emitting element 3 includes, for example, the bank 70 covering an edge 31E of the first electrode 31 and the light-emitting layer 80 covering an opening 70a of the bank 70. For example, when the light-emitting element 3 is formed in an island shape, as illustrated in FIG. 2B, a pattern (two kinds are illustrated) in which one light-emitting layer 80 covers the opening 70a of one bank is formed. When the light-emitting element 3 is formed in a strip shape, as illustrated in FIG. 2C, a pattern in which the continuous light-emitting layer 80 covers the openings 70a of the plurality of banks is formed. In other words, the light-emitting layer 80 may be formed in, for example, an island shape as illustrated in FIG. 2B or a strip shape as illustrated in FIG. 2C.

Further, a sealing layer (not illustrated) is provided on the second electrode 32. The sealing layer includes, for example, an inorganic sealing film that covers the second electrode 32, an organic layer formed of an organic buffer film that is an upper layer overlying the inorganic sealing film, and an inorganic sealing film that is an upper layer overlying the organic buffer film. The sealing layer prevents penetration of foreign matters such as water and oxygen into the display device 1. Further, the inorganic sealing film is an inorganic insulating film, and can be formed of, for example, a silicon oxide film, a silicon nitride film, a silicon oxynitride film, or a layered film thereof formed by CVD. The organic buffer film is a transparent organic film having a leveled effect, and can be formed of a coatable organic material such as an acrylic. Further, a function film (not illustrated) may be provided on the sealing layer. The function film has, for example, at least one of an optical compensation function, a touch sensor function, and a protection function.

The positive hole injected from the first electrode 31 and the electron injected from the second electrode 32 are transported to the light-emitting layer 80 via the first charge transport layer 41 and the second charge transport layer 42, respectively. Then, the positive hole and the electron transported to the light-emitting layer 80 recombine in the quantum dot to generate an exciton. Then, the exciton returns from an excited state to a ground state, and thus the quantum dot emits light. Note that, in the display device 1 according to the present embodiment, a top-emitting type in which light emitted from the light-emitting layer 80 is extracted from an opposite side to the array substrate 10 (upward direction in FIG. 1) is exemplified. However, the display device 1 may be a bottom-emitting type in which the light is extracted from an array substrate 10 side (downward direction in FIG. 1). In this case, the second electrode 32 may be formed of a reflective electrode, and the first electrode 31 may be formed of a transparent electrode.

Further, in the display device 1 according to the present embodiment, the first electrode 31 that is the anode electrode, the first charge transport layer 41 that is the hole transport layer, the light-emitting layer 80, the second charge transport layer 42 that is the electron transport layer, and the second electrode 32 that is the cathode electrode are layered in the order from the array substrate 10. However, the display device 1 may have a so-called invert structure in which the cathode electrode, the electron transport layer, the light-emitting layer 80, the hole transport layer, and the anode electrode are layered in the order from the array substrate 10.

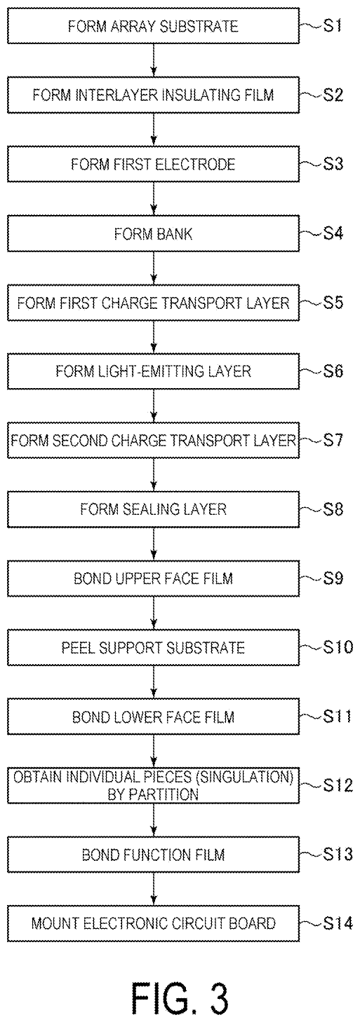

Next, the manufacturing method for the display device 1 will be described. FIG. 3 is a flowchart illustrating a manufacturing method for the display device 1 according to the present embodiment.

As illustrated in FIG. 3, in order to prepare the display device 1, first, the array substrate 10 is formed (step S1). The array substrate 10 is formed by forming a resin layer on a transparent support substrate (for example, a mother glass), forming a barrier layer on the resin layer, and forming a TFT on the barrier layer. Next, the interlayer insulating film 20 is formed (step S2). Next, the first electrode 31 is formed (step S3). Next, the bank 70 is formed (step S4).

Next, the first charge transport layer 41 is formed (step S5). The first charge transport layer 41 is formed by applying a colloidal solution including at least the first nanoparticle 61 and the first nanofiber 51 by ink-jet.

The viscosity of the colloidal solution at room temperature (from 20 to 25° C.) is preferably from 5 mPa·s to 20 mPa·s, and more preferably from 5 mPa·s to 10 mPa·s. This allows the colloidal solution to be suitably applied (ejected) by ink-jet.

Examples of the solvent (dispersion medium) for forming the colloidal solution include an organic solvent such as methyl alcohol, ethyl alcohol, hexane, methyl ethyl ketone (MEK), ethyl acetate, chloroform, tetrahydrofuran (THF), benzene, chlorobenzene, 1,2-dichlorobenzene, toluene, and propylene glycol monomethyl ether acetate (PGMEA), or water. In the present embodiment, since the viscosity of the colloidal solution can be adjusted by the first nanofiber 51, a degree of freedom in selection of the solvent (dispersion medium) can be increased, and generally speaking even a solvent with low viscosity that is unable to be applied by ink-jet can be used.

Specifically, for example, the viscosity of ethyl alcohol at 20° C. is 1.200 mPa·s, the viscosity of methyl ethyl ketone at 20° C. is 0.40 mPa·s, the viscosity of chlorobenzene at 20° C. is 0.8 mPa·s, the viscosity of 1,2-dichlorobenzene at 25° C. is 1.324 mPa·s, the viscosity of toluene at 20° C. is 0.5866 mPa·s, the viscosity of propylene glycol monomethyl ether acetate at 25° C. is 1.1 mPa·s, the viscosity of water at 20° C. is 1.002 mPa·s, and none are suitable for application by ink-jet. However, even with these solvents, by adding the first nanofiber 51, the viscosity of the colloidal solution at room temperature (from 20° C. to 25° C.) can be adjusted (thickened) to from 5 mPa·s to 20 mPa·s. Note that the amount of the first nanoparticle 61 in the colloidal solution is suitably approximately several wt. % from a perspective of charge transport properties.

Here, the first nanofiber 51 acts as a viscosity adjusting agent (thickener) of the colloidal solution, and adjusts the colloidal solution to the viscosity suitable for ink-jet. In other words, the first nanofiber 51 has a high viscosity thickening characteristic, and the viscosity (viscosity) and thixotropy of the solution (dispersion) can be controlled by adding the first nanofiber 51. Further, the non-uniform aggregation of the first nanoparticles 61 can be suppressed after drying of the colloidal solution.

In this way, by adding the first nanofiber 51 to the colloidal solution including the first nanoparticle 61 and the solvent (dispersion medium), the colloidal solution can be applied (ejected) by ink-jet regardless of the viscosity of the solvent, and drying unevenness (so-called coffee ring) can be prevented from occurring in droplets after the application. In addition, since the colloidal solution can be applied by ink-jet, the first charge transport layer 41 being uniform without unevenness in thickness and without cracking can be formed.

Then, a diameter of the first nanofiber 51 included in the first charge transport layer 41 is preferably smaller than a thickness of the first charge transport layer 41 (typically from 5 to 30 nm). Thus, a diameter from 3 to 30 nm is suitable, a diameter smaller than a diameter of the first nanoparticle 61 is more preferable, and a diameter as small as possible is even more preferable. When the diameter of the first nanofiber 51 exceeds 30 nm, unevenness readily occurs on a surface of the first charge transport layer 41, and flatness of an interface decreases, and thus light-emission characteristics may decrease. Further, when the diameter of the first nanofiber 51 exceeds 30 nm, a region in which the first nanoparticle 61 is not present in a film thickness direction of the first charge transport layer 41 may be formed.

Further, a length of the first nanofiber 51 included in the first charge transport layer 41 is suitably greater than the diameter of the first nanoparticle 61, is more preferably greater than or equal to twice the thickness of the first charge transport layer 41 and less than or equal to 1 μm, and is even more preferably from 60 nm to 1 μm, which is sufficiently greater than the thickness. When the length of the first nanofiber 51 is less than twice the thickness of the light-emitting layer 80, it is difficult for the first nanofiber 51 to be arranged in parallel (horizontally) in the surface of the first charge transport layer 41, and thus the unevenness readily occurs on the surface of the first charge transport layer 41. When the length of the first nanofiber 51 is greater than 1 μm, there is a risk that clogging of the nozzle when applied by ink-jet may occur. Further, patterning of the first charge transport layer 41 to be formed may be degraded.

By controlling the diameter and length of the first nanofiber 51 to be the diameter and length described above, the colloidal solution can be suitably applied (ejected) by ink-jet.

Note that, in the present specification, a relationship between the first nanoparticle 61 and the first nanofiber 51, and the like are described by using “diameter” as an indicator. Here, the “diameter” is intended to be a diameter assumed to be a true sphere in the first nanoparticle 61, and assumed to be a true circle in the first nanofiber 51. However, in practice, there are the first nanoparticle 61 that is not regarded as the true sphere and the first nanofiber 51 in which the cross-section is not regarded as the true circle. However, even when the first nanoparticle 61 has some distortions from the true sphere, the first nanoparticle 61 can perform substantially the same function as the first nanoparticle 61 of the true sphere. Further, even when the cross-section of the first nanofiber 51 is an elliptic shape or a strip shape having a distortion, the first nanofiber 51 can perform substantially the same function as the first nanofiber 51 in which the cross-section is the true circle. Therefore, the “diameter” in the present specification refers to a diameter when the first nanoparticle 61 is converted to the first nanoparticle 61 of the true sphere of the same volume for the first nanoparticle 61, and refers to a maximum width for the first nanofiber 51.

Further, the number of the first nanoparticles 61 included in the first charge transport layer 41 is preferably greater than the number of the first nanofibers 51. Specifically, a number ratio of the first nanofibers 51 to the first nanoparticles 61 (first nanofibers 51: first nanoparticles 61) is more preferably from 1:100 to 1:100,000,000, and even more preferably from 1:10,000 to 1:10,000,000. By controlling the number ratio of the first nanoparticles 61 and the first nanofibers 51 in this manner, an excellent charge transport layer can be formed.

To keep the viscosity of the colloidal solution at room temperature (from 20° C. to 25° C.) ranging from 5 mPa·s to 20 mPa·s, the amount of the first nanofiber 51 in the colloidal solution is preferably greater than 0 and not greater than 1 wt. %, and is preferably as low as possible while still affording a viscosity increasing effect. When the amount of the first nanofiber 51 exceeds 1 wt. %, the viscosity of the colloidal solution becomes too high, making the colloidal solution difficult to suitably apply (eject) by ink-jet. This may make it difficult to form a thin film. Further, the amount of the first nanoparticle 61 included in the first charge transport layer 41 relatively decreases, and thus light-emission characteristics may decrease. Note that, when the amount of the first nanofiber 51 is too small, the viscosity increasing effect cannot be obtained.

The first nanofiber 51 is not particularly limited as long as the first nanofiber 51 is transparent and has insulating properties, but a linear polysaccharide polymer (polysaccharide) is suitable. By modifying the polysaccharide polymer with a hydrophobic group, it can be readily and stably dispersed in an organic solvent. The first nanofiber 51 is more preferably a cellulose nanofiber in which glucose is a polysaccharide linked in a straight chain, a chitin nanofiber in which acetylglucosamine is a polysaccharide linked in a straight chain, and a lambda carrageenan used as a thickener for food products, even more preferably a cellulose nanofiber, and particularly preferably a TEMPO-oxidized cellulose nanofiber. A plurality of types of the first nanofibers 51 may be used in combination as necessary. Note that a molecule structure of a terminal end of the first nanofiber 51 differs depending on whether the first nanofiber 51 is dispersed in water or dispersed in an organic solvent.

The cellulose nanofiber can be readily and stably dispersed in water or an organic solvent, such as methyl alcohol, methyl ethyl ketone (MEK), ethyl acetate, toluene, and the like. The chitin nanofiber can be readily and stably dispersed in organic solvents, such as chloroform, tetrahydrofuran (THF), benzene, toluene, hexane, and the like.

For example, TEMPO(2,2,6,6-tetramethylpiperidine-1-oxyradical)oxidized cellulose nanofiber has a diameter of 3 nm, is transparent, is without scattering, is highly insulating (>100 TΩ), and has a high dielectric constant (from 5 to 6 F/m). The TEMPO-oxidized cellulose nanofiber is, for example, an oxidized cellulose nanofiber including a nitroxyl radical such as 2,2,6,6-tetramethylpiperidine-1-oxyradical.

Furthermore, even when the colloidal solution is applied by ink-jet, the first nanofiber 51 included in the colloidal solution after application, that is, the first nanofiber 51 included in the first charge transport layer 41, maintains a random state in the in-plane direction.

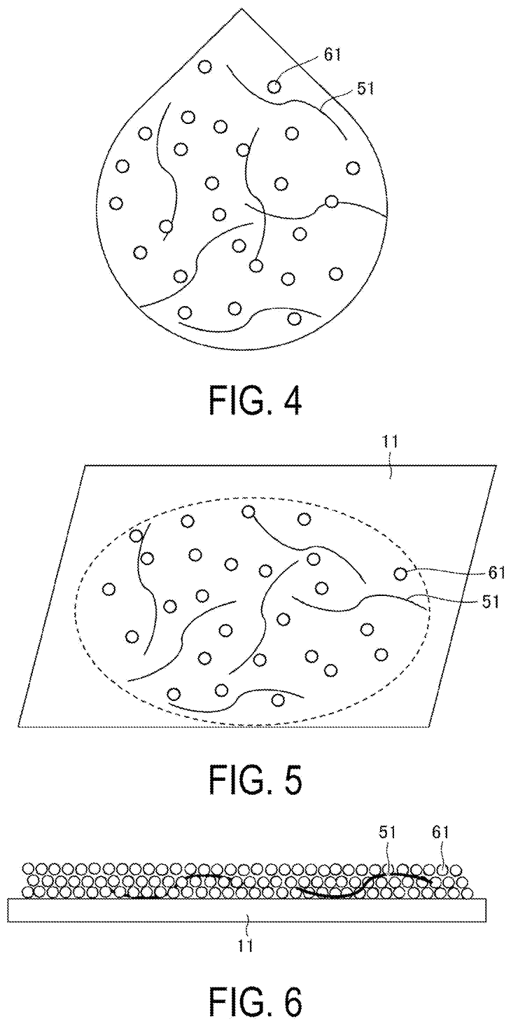

FIG. 4 is a diagram schematically illustrating a state of a colloidal solution (droplet) ejected by ink-jet. As illustrated in FIG. 4, the first nanoparticles 61 and the first nanofibers 51 in the droplet are in a random state.

FIG. 5 is a plan view schematically illustrating a state of the colloidal solution applied (dropped) onto a substrate 11 and dried, i.e., the light-emitting layer 80. FIG. 6 is a cross-sectional view schematically illustrating a state of the colloidal solution applied (dropped) onto the substrate 11 and dried, i.e., the light-emitting layer 80. As illustrated in FIGS. 5 and 6, the first nanoparticles 61 are uniformly applied across the entire drip area, and are disposed three-dimensionally while the first nanofiber 51 is present so as to be sewn between the first nanoparticles 61, is oriented with a length direction aligned with the substrate plane (surface) of the substrate 11, and maintains a random state in the in-plane direction. The first nanofiber 51 is present in the random state in the in-plane direction so as to be sewn between the first nanoparticles 61, and thus the first charge transport layer 41 being uniform without unevenness in thickness and without cracking is formed. In other words, since the first charge transport layer 41 being uniform is formed, the display device 1 can uniformly emit light.

Next, the light-emitting layer 80 is formed (step S6). Note that, in the method for forming the light-emitting layer 80, a difference from the method for forming the first charge transport layer 41 described above will be described, and description of a similar content will be omitted.

The light-emitting layer 80 is formed by applying a colloidal solution including a quantum dot by ink-jet. In the method for forming the light-emitting layer 80, the colloidal solution may or may not include a ligand. In a case in which the colloidal solution does not include a ligand, the solvent is not limited by the ligand. In addition, the colloidal solution preferably does not include a host material.

The quantum dot is a particulate semiconductor having a diameter of from 2 to 10 nm (number of atoms for 100 to 10 thousand) formed of group elements of group II-VI, III-V, or IV-VI, and is used as a luminophore. The quantum dots may differ from each other in material, elemental concentration, and crystal structure in the center portion and the outer shell portion. Furthermore, the quantum dots may have different band gaps in the center portion and the outer shell portion, and the band gap may be larger in the outer shell than in the center portion. The quantum dots are dispersed in a solvent (dispersion medium) to form a colloidal solution. Note that, in order to suppress aggregation of the quantum dots in the colloidal solution and to increase the dispersibility and stability of the quantum dots, atoms and organic molecules may be attached to the surface of the quantum dots as ligands. Examples of the organic molecule that is a ligand include alkylthiol, alkylamine, carboxylic acid, oleic acid, organic silane, and the like.

Note that the first nanofiber 51 may be further included in the light-emitting layer 80 as necessary. In other words, the light-emitting layer 80 may be a layer that is formed by applying a solution including the first nanofiber 51 by ink-jet and includes the first nanofiber 51.

Next, the second charge transport layer 42 is formed (step S7). The second charge transport layer 42 is formed by applying a colloidal solution including at least the second nanoparticle 62 and the second nanofiber 52 by ink-jet. The method for forming the second charge transport layer 42 is similar to the method of forming the first charge transport layer 41 described above, and thus description thereof will be omitted. Note that the first nanofiber 51 and the second nanofiber 52 may be the same type or may be different types. In other words, the first nanofiber 51 and the second nanofiber 52 may be equal in material and shape. Specifically, for example, both of materials of the first nanofiber 51 and the second nanofiber 52 may be TEMPO-oxidized cellulose nanofibers. Further, for example, a diameter and a length of the first nanofiber 51 and a diameter and a length of the second nanofiber 52 may be equivalent.

Next, the sealing layer is formed (step S8). Next, an upper face film is bonded onto the sealing layer (step S9). Next, the support substrate is peeled from the resin layer by irradiation with laser light and the like (step S10). Next, a lower face film is bonded to a lower face of the resin layer 12 (step S11). Next, a layered body in which each layer is layered is partitioned, and a plurality of individual pieces are obtained (step S12). Next, a function film is bonded to the obtained individual pieces (step S13). Subsequently, an electronic circuit board (for example, an IC chip and an FPC) is mounted on a portion (terminal portion) located outward (a non-display region, frame) from a display region in which the plurality of pixels 2 are formed (step S14). In this way, the display device 1 according to the present embodiment can be manufactured. Note that steps S1 to S13 are performed by a manufacturing apparatus of the display device (including a film formation apparatus configured to perform each of steps S1 to S5).

Note that the flexible display device 1 is described above, but when manufacturing a non-flexible display device 1, formation of a resin layer, replacement of a base material, and the like are not required in general. Thus, for example, a layering step of steps S2 to S7 is performed on the array substrate 10 that is the glass substrate, and subsequently, processing proceeds to step S11.

As described above, an aspect of the disclosure can provide the display device 1 in which the first charge transport layer 41 being uniform without unevenness in thickness and without cracking is formed. Further, as described above, an aspect of the disclosure can provide a manufacturing method for the display device 1 in which a colloidal solution can be applied (ejected) by ink-jet regardless of viscosity of a solvent, and drying unevenness (so-called coffee ring) does not occur in droplets after the application.

### Second Embodiment

Next, a second embodiment will be described. Note that a difference from the first embodiment will be mainly described, and a description of contents overlapping the first embodiment will be omitted. Note that a configuration of a first charge transport layer 41 is different between the first embodiment and the second embodiment.

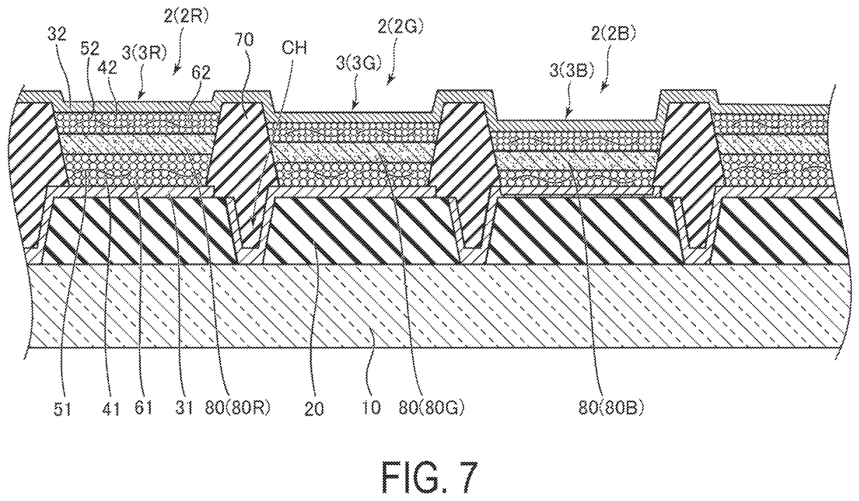

FIG. 7 is a cross-sectional view illustrating a general configuration of a display device 1 according to the present embodiment. In the display device 1 according to the present embodiment, a film thickness of the first charge transport layer 41 is different in a red light-emitting element 3R, a green light-emitting element 3G, and a blue light-emitting element 3B. Specifically, as illustrated in FIG. 7, the film thickness of the first charge transport layer 41 included in the red light-emitting element 3R is greater than the film thickness of the first charge transport layer 41 included in the green light-emitting element 3G, and, furthermore, the film thickness of the first charge transport layer 41 included in the green light-emitting layer 80G is greater than the film thickness of the first charge transport layer 41 included in the blue light-emitting element 3B. More specifically, the film thickness of the first charge transport layer 41 included in the red light-emitting element 3R is 150 nm. Further, the film thickness of the first charge transport layer 41 included in the green light-emitting element 3G is 110 nm. Further, the film thickness of the first charge transport layer 41 included in the blue light-emitting element 3B is 40 nm. With such a configuration, extraction efficiency into a front direction is improved by an interference effect of light emitted from a light-emitting layer 80 of each light-emitting element 3 on a layer structure interface in the element. As a result, front brightness (the brightness of light extracted upward in FIG. 7) of the display device 1 can be improved.

### Third Embodiment

Next, a third embodiment will be described. Note that a difference from the above-described embodiment will be mainly described, and a description of contents overlapping the above-described embodiments will be omitted. Note that a configuration of a second charge transport layer 42 is different between the above-described embodiments and the third embodiment.

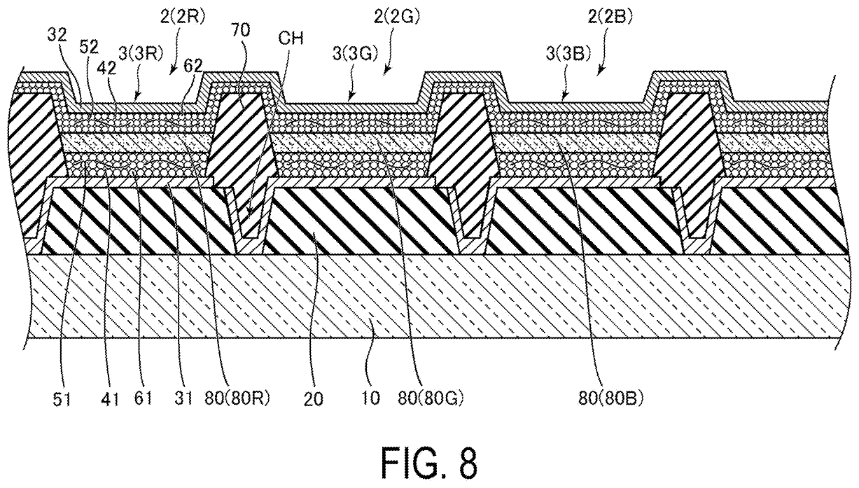

FIG. 8 is a cross-sectional view illustrating a general configuration of a display device 1 according to the present embodiment. In the display device 1 according to the present embodiment, the second charge transport layer 42 is formed in common in a red light-emitting element 3R, a green light-emitting element 3G, and a blue light-emitting element 3B. Further, a second electrode 32 according to the present embodiment is a common electrode formed in common to light-emitting elements 3. Specifically, as illustrated in FIG. 8, the second charge transport layer 42 according to the present embodiment is not formed in an island shape in a region divided by a bank 70, and is continuously formed so as to cover a red light-emitting layer 80R, a green light-emitting layer 80G, a blue light-emitting layer 80B, and the bank 70. With such a configuration, the second charge transport layer 42 does not need to be formed by separate patterning for each light-emitting layer 80 by an ink-jet method, and can be collectively formed by, for example, a spin coating method. As a result, the display device 1 can be readily manufactured.

### Modified Example

A main embodiment according to the disclosure has been described above, but the disclosure is not limited to the above-described embodiments.

In the above-described embodiments, the light-emitting layer 80 includes the quantum dot. However, the light-emitting layer 80 according to an aspect of the disclosure may have a configuration without the quantum dot. In this case, the light-emitting layer 80 may be formed of, for example, an organic fluorescent material or a phosphorescent material.

Further, in the above-described embodiments, the first charge transport layer 41 and the second charge transport layer 42 include the first nanofiber 51 and the second nanofiber 52, respectively. In other words, both of the first charge transport layer 41 and the second charge transport layer 42 include the nanofiber. However, the nanofiber may be included in at least one of the first charge transport layer 41 and the second charge transport layer 42. Even with such a configuration, occurrence of unevenness in film thickness due to drying unevenness of droplets after application can be suppressed in the display device 1.

Further, in the above-described embodiments, the first charge transport layer 41 includes the first nanoparticle 61 that is a material having hole transport properties. However, the first charge transport layer 41 may not include the first nanoparticle 61, and may include an organic material having the hole transport properties (for example, PEDOT: PSS, PVK, TFB, poly-TPD, or the like). Even with such a configuration, occurrence of unevenness in film thickness due to drying unevenness of droplets after application can be suppressed in the first charge transport layer 41.

Further, in the above-described embodiments, the second charge transport layer 42 includes the second nanoparticle 62 that is a material having electron transport properties. However, the second charge transport layer 42 may not include the second nanoparticle 62, and may include an organic material having the electron transport properties (for example, polyoxadiazole, a soluble Alq₃ polymer, or the like). Even with such a configuration, occurrence of unevenness in film thickness due to drying unevenness of droplets after application can be suppressed in the second charge transport layer 42.

Further, the elements described in the above-described embodiments and the modified examples may be appropriately combined in a range in which a contradiction does not arise.

1. A display device comprising:
a plurality of pixels,
wherein each of the plurality of pixels includes
a first electrode,
a second electrode,
a light-emitting layer provided between the first electrode and the second electrode,
a first charge transport layer provided between the first electrode and the light-emitting layer, and
a second charge transport layer provided between the second electrode and the light-emitting layer, and
the first charge transport layer includes a first charge transport material and a first nanofiber,
wherein the first charge transport material is a first nanoparticle.

2. (canceled)

3. The display device according to claim 1,
wherein the light-emitting layer includes a quantum dot.

4. The display device according to claim 1,
wherein the plurality of pixels include a predetermined luminescent color for each of the plurality of pixels, and
the first charge transport layer is different in thickness depending on the luminescent color in each of the plurality of pixels.

5. The display device according to claim 1,
wherein the plurality of pixels include a predetermined luminescent color for each of the plurality of pixels, and
the first charge transport layer is different in material depending on the luminescent color in each of the plurality of pixels.

6. The display device according to claim 1,
wherein the second electrode is a common electrode, and
the second charge transport layer is continuously formed across the plurality of pixels.

7. The display device according to claim 1,
wherein the number of a first nanoparticle included in the first charge transport layer is greater than the number of the first nanofiber included in the first charge transport layer.

8. The display device according to claim 1,
wherein a diameter of the first nanofiber is smaller than a diameter of the first nanoparticle, and a length of the first nanofiber is greater than a diameter of the first nanoparticle.

9. The display device according to claim 1,
wherein a length of the first nanofiber is greater than or equal to twice a thickness of the first charge transport layer and less than or equal to 1 μm.

10. The display device according to claim 1,
wherein the first nanofiber has insulating properties.

11. The display device according to claim 1,
wherein the first nanofiber has optical transparency.

12. The display device according to claim 1,
wherein the first nanofiber is a cellulose nanofiber.

13. The display device according to claim 1,
wherein the first nanofiber is an oxidized cellulose nanofiber including a nitroxyl radical.

14. The display device according to claim 1,
wherein the second charge transport layer includes a second charge transport material and a second nanofiber.

15. The display device according to claim 14,
wherein the second charge transport material is a second nanoparticle.

16. The display device according to claim 15,
wherein the number of the second nanoparticle included in the second charge transport layer is greater than the number of the second nanofiber included in the second charge transport layer.

17. The display device according to claim 15,
wherein a diameter of the second nanofiber is smaller than a diameter of the second nanoparticle, and a length of the second nanofiber is greater than a diameter of the second nanoparticle.

18. The display device according to claim 14,
wherein a length of the second nanofiber is greater than or equal to twice a thickness of the second charge transport layer and less than or equal to 1 μm.

19. The display device according to claim 14,
wherein the second nanofiber has insulating properties.

20. The display device according to claim 14,
wherein the second nanofiber has optical transparency.

21. The display device according to claim 14,
wherein the second nanofiber is a cellulose nanofiber.

22-28. (canceled)
